(19) United States
(12) Patent Application Publication
(10) Pub. No.: US 2023/0125216 A1
(43) Pub. Date: Apr. 27, 2023

(54) ELECTROMAGNETIC WAVE TRANSMISSIVE METALLIC LUSTER MEMBER

(71) Applicant: NITTO DENKO CORPORATION, Ibaraki-shi, Osaka (JP)

(72) Inventors: Ryotaro YOKOI, Ibaraki-shi, Osaka (JP); Takahiro NAKAI, Ibaraki-shi, Osaka (JP); Tomotake NASHIKI, Ibaraki-shi, Osaka (JP)

(21) Appl. No.: 17/911,762

(22) PCT Filed: Mar. 1, 2021
(86) PCT No.: PCT/JP2021/007661

§ 371 Date: Sep. 15, 2022

(30) Foreign Application Priority Data
Mar. 17, 2020 (JP) 2020-046758

(51) Int. Cl. C23C 28/00

(52) U.S. Cl. CPC C23C 28/32; C23C 14/086

(57) ABSTRACT

The present invention relates to an electromagnetic wave transmissive metallic luster member including: a substrate; an indium oxide-containing layer provided on the substrate in a continuous state; and a metal layer formed on the indium oxide-containing layer, in which the metal layer includes, in at least a part thereof, a plurality of portions which are in a discontinuous state each other, and a sheet resistance of a laminate of the metal layer and the indium oxide-containing layer is 2.50 E + 8 Ω/□ or more.

### TECHNICAL FIELD

The present invention relates to an electromagnetic wave transmissive metallic luster member.

### BACKGROUND ART

A member having electromagnetic wave transmitting property and metallic luster has both high-quality feeling of appearance originated from its metallic luster and electromagnetic wave transmitting property. Therefore, it has been suitably used in an apparatus transmitting and receiving electromagnetic waves, conventionally.

When a metal is used as a metallic luster member, transmission and reception of electromagnetic waves are substantially impossible or disturbed. Therefore, in order not to disturb transmission and reception of electromagnetic waves and not to impair a design, an electromagnetic wave transmissive metallic luster member having both metallic luster and electromagnetic wave transmitting property has been required.

Such an electromagnetic wave transmissive metallic luster member is expected to be applied to, as an apparatus transmitting and receiving electromagnetic waves, various devices which require communication, for example, electronic devices such as a door handle of an automobile provided with a smart key, an in-vehicle communication device, a mobile phone, and a personal computer. Furthermore, in recent years, with the development of IoT technologies, the electromagnetic wave transmissive metallic luster member is also expected to be applied in wide fields, for example, household electric appliances such as refrigerators and living equipment that cannot conventionally perform communication or the like.

Regarding the electromagnetic wave transmissive metallic luster member, Patent Literature 1 describes an electromagnetic wave transmissive metallic luster member including an indium oxide-containing layer provided on a surface of a substrate and a metal layer laminated on the indium oxide-containing layer, in which the metal layer includes, in at least a part thereof, a plurality of portions which are in a discontinuous state each other.

### Citation List

### Patent Literature

Patent Literature 1: Japanese Patent No. 6400062

### SUMMARY OF INVENTION

### Technical Problem

In the related art, when a thickness of a metal layer in the electromagnetic wave transmissive metallic luster member is increased, reflectance is increased, and metallic luster is easily obtained. However, when the thickness of the metal layer is increased, metals formed in an island shape overlap with each other, and a resistance value is rapidly decreased, so that electromagnetic wave transmitting property is significantly impaired. Therefore, there is a trade-off relationship between the reflectance and the electromagnetic wave transmitting property.

The present invention has been made to solve the above problem in the related art, and an object of the present invention is to provide an electromagnetic wave transmissive metallic luster member having high reflectance and exhibiting excellent electromagnetic wave transmitting property.

### Solution to Problem

As a result of intensive studies to solve the above problem, the present inventors have found that the above problem can be solved by setting a sheet resistance within a specific range, and have completed the present invention.

That is, the present invention is as follows.
An electromagnetic wave transmissive metallic luster member including:
   a substrate;
   an indium oxide-containing layer provided on the substrate in a continuous state; and
   a metal layer formed on the indium oxide-containing layer, in which
   the metal layer includes, in at least a part thereof, a plurality of portions which are in a discontinuous state each other, and
   a sheet resistance of a laminate of the metal layer and the indium oxide-containing layer is 2.50 E + 8 Ω/□ or more.
The electromagnetic wave transmissive metallic luster member according to [1], in which
   the indium oxide-containing layer has a thickness of 3.3 nm to 4.6 nm.
The electromagnetic wave transmissive metallic luster member according to [1] or [2], in which
   the indium oxide-containing layer contains any one of indium oxide (In₂O₃), indium tin oxide (ITO), or indium zinc oxide (IZO).
The electromagnetic wave transmissive metallic luster member according to any one of [1] to [3], in which
   the metal layer is a layer containing aluminum or an aluminum alloy.
The electromagnetic wave transmissive metallic luster member according to any one of [1] to [4], in which
   the metal layer has a thickness of 10 nm to 200 nm.
The electromagnetic wave transmissive metallic luster member according to any one of [1] to [5], in which
   the plurality of portions is formed in an island shape.
The electromagnetic wave transmissive metallic luster member according to any one of [1] to [6], in which
   the substrate is any one of a substrate film, a resin molded product substrate, a glass substrate, or an article to which metallic luster is to be imparted.

### Advantageous Effects of Invention

According to the present invention, it is possible to provide an electromagnetic wave transmissive metallic luster member having high reflectance and exhibiting excellent electromagnetic wave transmitting property.

### BRIEF DESCRIPTION OF DRAWINGS

FIG. 1 is a schematic cross-sectional view of an electromagnetic wave transmissive metallic luster member according to an embodiment of the present invention.

FIG. 2 is a view showing an electron micrograph (an SEM image) of a surface of the electromagnetic wave transmissive metallic luster member according to the embodiment of the present invention.

FIG. 3 is a view showing an electron micrograph (a TEM image) of a cross section of the electromagnetic wave transmissive metallic luster member according to the embodiment of the present invention.

FIG. 4 is a diagram illustrating a method of measuring a thickness of a metal layer of the electromagnetic wave transmissive metallic luster member according to the embodiment of the present invention.

FIG. 5 is a diagram showing a relationship between a film thickness of an indium oxide-containing layer and a sheet resistance of each of electromagnetic wave transmissive metallic luster members of Examples and Comparative Examples of the present invention.

### DESCRIPTION OF EMBODIMENTS

Hereinafter, the present invention will be described in detail with reference to the accompanying drawings, but the present invention is not limited to the following embodiment, and can be optionally modified and implemented without departing from the gist of the present invention. The expression “to” indicating a numerical range is used to include numerical values described before and after thereof as a lower limit value and an upper limit value.

### Basic Configuration

An electromagnetic wave transmissive metallic luster member according to an embodiment of the present invention includes: a substrate; an indium oxide-containing layer provided on the substrate in a continuous state; and a metal layer formed on the indium oxide-containing layer. The metal layer includes, in at least a part thereof, a plurality of portions which are in a discontinuous state each other, and a sheet resistance of a laminate of the metal layer and the indium oxide-containing layer is 2.50 E + 8 Ω/□ or more.

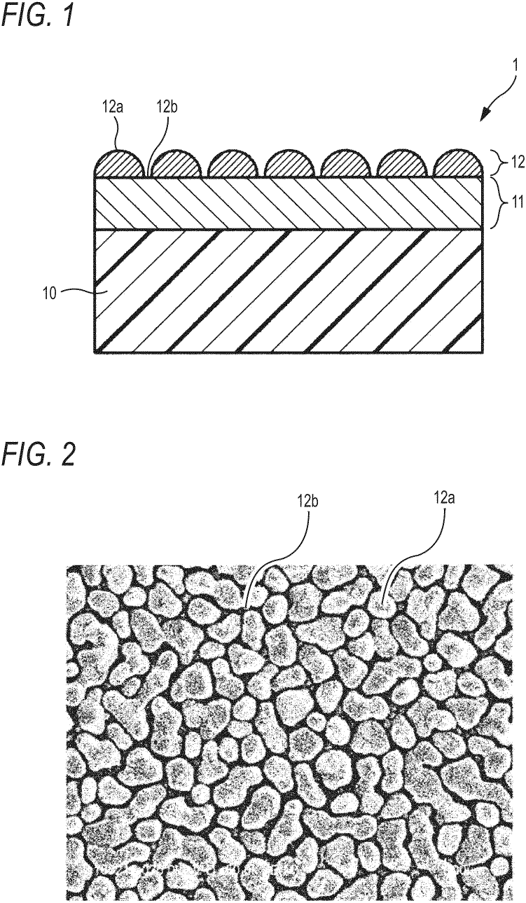

FIG. 1 shows a schematic cross-sectional view of an electromagnetic wave transmissive metallic luster member 1 according to an embodiment of the present invention. FIG. 2 shows an example of an electron micrograph (an SEM image) of a surface of the electromagnetic wave transmissive metallic luster member 1 according to the embodiment of the present invention.

As shown in FIG. 1, the electromagnetic wave transmissive metallic luster member 1 includes a substrate 10, an indium oxide-containing layer 11 formed on the substrate 10, and a metal layer 12 formed on the indium oxide-containing layer 11.

The indium oxide-containing layer 11 is provided on a surface of the substrate 10. The indium oxide-containing layer 11 may be provided directly on the surface of the substrate 10, or may be provided indirectly via a protective film or the like provided on the surface of the substrate 10. The indium oxide-containing layer 11 is preferably provided on the surface of the substrate 10 in a continuous state, in other words, without any gaps. By being provided in a continuous state, it is possible to improve smoothness and corrosion resistance of the indium oxide-containing layer 11, and thus it is possible to improve smoothness and corrosion resistance of the electromagnetic wave transmissive metallic luster member 1. It is also easy to form the indium oxide-containing layer 11 without variation in the surface.

The metal layer 12 is laminated on the indium oxide-containing layer 11. The metal layer 12 includes a plurality of portions 12a. By being laminated on the indium oxide-containing layer 11, these portions 12a are in a discontinuous state each other in at least a part thereof, in other words, separated from each other by a gap 12b in at least a part thereof. Since these portions 12a are separated from each other by the gap 12b, a sheet resistance of these portions 12a is increased, and an interaction with radio waves is reduced, so that the radio waves can be transmitted. Each of these portions 12a is an aggregate of sputtered particles formed by vapor deposition, sputter, or the like of a metal. When the sputtered particles form a thin film on a substrate such as the substrate 10, surface diffusivity of the particles on the substrate affects a shape of the thin film.

The term “discontinuous state” as used herein means a state in which these portions 12a are separated from each other by the gap 12b, and as a result, these portions 12a are electrically insulated from each other. By the electrical insulation, the sheet resistance is increased, and desired electromagnetic wave transmitting property is obtained. A form of discontinuity is not particularly limited, and examples thereof include an island shape and a crack.

Here, the term “island shape” means a structure in which, as shown in the electron micrograph (the SEM image) of the surface of the metal layer of the electromagnetic wave transmissive metallic luster member in FIG. 2, particles which are aggregates of sputtered particles are independent from each other, and the particles are spread in a state of being slightly separated from each other or being partially in contact with each other.

A crack structure is a structure in which a metal thin film is divided by a crack.

The metal layer 12 having a crack structure can be formed, for example, by providing a metal thin film layer on the indium oxide-containing layer formed on the substrate and bending and stretching the metal thin film layer to cause a crack in the metal thin film layer. At this time, the metal layer 12 having the crack structure can be easily formed by providing, between the indium oxide-containing layer and the metal thin film layer, a brittle layer made of a material having poor stretch ability, that is, easily forming cracks by stretching.

As described above, the form in which the metal layer 12 is discontinuous is not particularly limited, but it is preferable to have an “island shape” from a viewpoint of productivity.

Electromagnetic wave transmitting property of the electromagnetic wave transmissive metallic luster member 1 is correlated with a sheet resistance.

A sheet resistance of a laminate of the metal layer and the indium oxide-containing layer of the electromagnetic wave transmissive metallic luster member 1 needs to be 2.50 E + 8 Ω/□ or more, and in this case, an attenuation amount of radio wave transmission in a microwave band (28 GHz) is about less than 0.1 [-dB].

The attenuation amount of radio wave transmission in the microwave band (28 GHz) is preferably less than 10 [-dB], more preferably less than 5 [-dB], and still more preferably less than 2 [-dB]. When the attenuation amount of radio wave transmission in the microwave band (28 GHz) is 10 [-dB] or more, there is a problem that 90% or more of radio waves are blocked.

The sheet resistance of the electromagnetic wave transmissive metallic luster member 1 is preferably 1.00 E + 10 Ω/□ or more, and more preferably 1.00 E + 12 Ω/□ or more.

When an electric resistance value is low, a leakage current may cause damage to an electric circuit or the like, and the damage can be prevented by increasing the resistance. The sheet resistance of the electromagnetic wave transmissive metallic luster member 1 can be measured by an eddy current measurement method in accordance with JIS-Z2316-1:2014.

The sheet resistance of the electromagnetic wave transmissive metallic luster member 1 can be adjusted by a film thickness of the indium oxide-containing layer, a film thickness and a state of the metal layer, and the like.

The attenuation amount of radio wave transmission and the sheet resistance of the electromagnetic wave transmissive metallic luster member 1 are affected by a material, a thickness, or the like of the indium oxide-containing layer 11 or the metal layer 12.

### Substrate

From a viewpoint of electromagnetic wave transmitting property, examples of the substrate 10 include a resin, a glass, and ceramics.

The substrate 10 may be any one of a substrate film, a resin molded product substrate, a glass substrate, or an article to which metallic luster is to be imparted.

More specifically, as the substrate film, for example, a transparent film made of a homopolymer or a copolymer such as polyethylene terephthalate (PET), polyethylene naphthalate (PEN), polybutylene terephthalate, polyamide, polyvinyl chloride, polycarbonate (PC), cycloolefin polymer (COP), polystyrene, polypropylene (PP), polyethylene, polycycloolefin, polyurethane, acrylic (PMMA), or ABS can be used.

According to these materials, brilliance and electromagnetic wave transmitting property are not affected. However, from a viewpoint of later forming the indium oxide-containing layer 11 and the metal layer 12, the substrate film preferably can withstand high temperature environment such as an environment in vapor deposition and sputter. Therefore, among the above materials, for example, polyethylene terephthalate, polyethylene naphthalate, acrylic, polycarbonate, cycloolefin polymer, ABS, polypropylene, and polyurethane are preferred. Among these, polyethylene terephthalate, cycloolefin polymer, polycarbonate, and acrylic are preferred in terms of a good balance between heat resistance and cost.

The substrate film may be a single-layer film or a laminated film. From a viewpoint of ease of processing and the like, a thickness is preferably, for example, about 6 µm to 250 µm. In order to increase an adhesion force to the indium oxide-containing layer 11 and the metal layer 12, a plasma treatment, an easy adhesion treatment, or the like may be performed. It is preferable that no particles are contained.

Here, it should be noted that the substrate film is merely an example of a target (the substrate 10) having a surface on which the indium oxide-containing layer 11 can be formed. As described above, in addition to the substrate film, the substrate 10 also includes the resin molded product substrate, the glass substrate, and the article itself to which metallic luster is to be imparted. Examples of the resin molded product substrate and the article to which metallic luster is to be imparted include a structural part for a vehicle, a vehicle-mounted article, a housing of an electronic device, a housing of a home appliance, a structural part, a machine part, various automobile parts, a part for an electronic device, furniture, a household goods application such as kitchen goods, a medical device, a part of a building member, and other structural parts and exterior parts.

### Indium Oxide-Containing Layer

The indium oxide-containing layer 11 is formed on the substrate 10. The indium oxide-containing layer 11 may be provided directly on the surface of the substrate 10, or may be provided indirectly via the protective film or the like provided on the surface of the substrate 10. The indium oxide-containing layer 11 is preferably provided on the surface of the substrate 10, to which metallic luster is to be imparted, in a continuous state, in other words, without any gaps. By being provided in a continuous state, it is possible to improve the smoothness and the corrosion resistance of the indium oxide-containing layer 11, and thus it is possible to improve smoothness and corrosion resistance of the metal layer 12 and the electromagnetic wave transmissive metallic luster member 1. It is also easy to form the indium oxide-containing layer 11 without variation in the surface.

In this way, by providing the indium oxide-containing layer 11 on the substrate 10, that is, by forming the indium oxide-containing layer 11 on the substrate 10 and laminating the metal layer 12 to be described later thereon, the metal layer 12 can be easily formed in a discontinuous state. Although details of a mechanism are not necessarily clear, it is considered that when sputtered particles obtained by vapor deposition or sputter of a metal form a thin film on a substrate, surface diffusivity of the particles on the substrate affects a shape of the thin film, and a discontinuous structure is easily formed when a temperature of the substrate is high and wettability of a metal layer with respect to the substrate is small. It is considered that by providing an indium oxide-containing layer on the substrate, the surface diffusivity of the metal particles on the surface is promoted, and the metal layer is easily grown in a discontinuous state.

The indium oxide-containing layer 11 may contain a metal-containing material such as indium oxide (In₂O3), indium tin oxide (ITO), or indium zinc oxide (IZO). When the indium oxide-containing layer 11 contains the metal-containing material, a continuous film can also be formed along the surface of the substrate, and in this case, it is easy for the metal layer 12 laminated on the indium oxide-containing layer 11 to have, for example, an island-shaped discontinuous structure, and thus it is preferable to contain the metal-containing material. Further, in this case, the metal layer 12 easily contains not only tin (Sn) or indium (In) but also various metals such as aluminum, which are typically difficult to form a discontinuous structure and are difficult to apply to the present application.

A content ratio (content ratio = (SnO₂/(In₂O₃ + SnO₂)) × 100) which is a mass ratio of tin oxide (SnO₂) contained in ITO is not particularly limited, but is, for example, 2.5 mass% to 30 mass%, and more preferably 3 mass% to 10 mass%. A content ratio (content ratio = (ZnO/(In₂O₃ + ZnO)) × 100) which is a mass ratio of zinc oxide (ZnO) contained in IZO is, for example, 2 mass% to 20 mass%.

A thickness of the indium oxide-containing layer 11 is preferably 4.6 nm or less, more preferably 4.4 nm or less, and still more preferably 4.0 nm or less in order to improve the sheet resistance and the electromagnetic wave transmitting property. On the other hand, in order to make the laminated metal layer 12 in a discontinuous state and to easily obtain high reflectance, the thickness is preferably 3.3 nm or more, more preferably 3.5 nm or more, and still more preferably 3.8 nm or more.

When the thickness of the indium oxide-containing layer 11 is 3.3 nm or more and 4.6 nm or less, the metal layer 12 formed on the indium oxide-containing layer 11 is easily made in a discontinuous state and the sheet resistance of the electromagnetic wave transmissive metallic luster member is easily set to 2.50 E + 8 Ω/□ or more. As a result, it is easy to obtain an electromagnetic wave transmissive metallic luster member exhibiting high reflectance and having excellent electromagnetic wave transmitting property.

### Metal Layer

The metal layer 12 is formed on the indium oxide-containing layer 11. The metal layer 12 is a layer having a metallic appearance, and is preferably a layer having metallic luster. A material for forming the metal layer 12 is not particularly limited, and may include a metal or a resin, or may include a metal and a resin.

A thickness of the metal layer 12 in the electromagnetic wave transmissive metallic luster member according to the embodiment of the present invention is not particularly limited as long as the sheet resistance can be set to 2.50 E + 8 Ω/□ or more, and for example, the thickness can be set in a wide range of 10 nm to 200 nm. Within this range, the yield is improved, and stable production can be realized.

From a viewpoint of exhibiting sufficient metallic luster, the thickness of the metal layer 12 is preferably 10 nm or more, and on the other hand, from viewpoints of the sheet resistance and the electromagnetic wave transmitting property, the thickness is preferably 200 nm or less. The thickness of the metal layer 12 is more preferably 10 nm to 100 nm, and still more preferably 10 nm to 70 nm. This thickness is also suitable for forming a uniform film with high productivity and obtaining an electromagnetic wave transmissive metallic luster member having high reflectance.

The metal layer 12 is formed on the indium oxide-containing layer 11, and includes, in at least a part thereof, the plurality of portions which are in a discontinuous state each other.

When the metal layer 12 is in a continuous state on the indium oxide-containing layer 11, the sufficient metallic luster can be obtained, but the attenuation amount of radio wave transmission is very large, and therefore, the electromagnetic wave transmitting property cannot be obtained.

As a matter of course, the metal layer 12 can exhibit sufficient brilliance, and the metal layer 12 preferably has a relatively low melting point. This is because the metal layer 12 is preferably formed by growth of a thin film using sputtering. For this reason, as the metal layer 12, a metal having a melting point of about 1100° C. or less is suitable, and for example, it is preferable to include any one of at least one metal selected from aluminum (Al), zinc (Zn), lead (Pb), copper (Cu), and silver (Ag), or an alloy containing the metal as a main component. Particularly, the metal layer 12 more preferably contains aluminum or an aluminum alloy from viewpoints of brilliance, stability, prices, and the like of a substance. When an aluminum alloy is used, an aluminum content is preferably 50 mass% or more.

An equivalent circle diameter of the portion 12a of the metal layer 12 is not particularly limited, but is usually about 10 nm to 1000 nm. An average particle diameter of the plurality of portions 12a means an average value of the equivalent circle diameters of the plurality of portions 12a.

The equivalent circle diameter of the portion 12a is a diameter of a perfect circle corresponding to an area of the portion 12a.

A distance between the portions 12a is not particularly limited, but is usually about 10 nm to 1000 nm.

### Other Layers

In addition to the indium oxide-containing layer 11 and the metal layer 12 described above, the electromagnetic wave transmissive metallic luster member 1 according to the embodiment of the present invention may include other layers depending on an application.

Examples of the other layers include an optical adjustment layer (a color adjustment layer) such as a high refractive material for adjusting an appearance such as a color, a protective layer (a scratch resistance layer) for improving durability such as scratch resistance, a barrier layer (a corrosion resistance layer), an easy adhesion layer, a hard coat layer, an antireflection layer, a light extraction layer, and an antiglare layer.

### Method for Producing Electromagnetic Wave Transmissive Metallic Luster Member

An example of a method for producing the electromagnetic wave transmissive metallic luster member according to the present embodiment will be described. Although not particularly described, even if a substrate other than the substrate film is used, the electromagnetic wave transmissive metallic luster member can also be produced by the same method.

When the indium oxide-containing layer 11 is formed on the substrate 10, the indium oxide-containing layer 11 is formed on the substrate 10 by vacuum vapor deposition, sputtering, ion plating, or the like before the metal layer 12 is formed. However, sputtering is preferred because the thickness can be strictly controlled even in a large area.

When the indium oxide-containing layer 11 is formed by sputtering, a metal target containing indium as a main component is not particularly limited, and may contain, for example, tin (Sn), zinc (Zn), and the like in addition to the indium. A compositional formula can be represented by InₓM₁₋ₓ (0.7 ≤ x ≤ 1, M = at least one metal element selected from Sn and Zn). Here, the “main component” means a component having a highest content ratio (on a mass basis) among all components in the metal target.

The indium is preferably contained in the metal target in an amount of 70 mass% or more, and more preferably 90 mass% or more.

When tin (Sn) is contained, the tin (Sn) is preferably contained in the metal target in an amount of, for example, 2.5 mass% to 30 mass%, and more preferably 3 mass% to 10 mass%.

When zinc (Zn) is contained, the zinc (Zn) is preferably contained in the metal target in an amount of, for example, 2 mass% to 20 mass%, and more preferably 5 mass% to 15 mass%.

As an inert gas, an inert gas such as argon or nitrogen is widely used. A reactive gas such as an oxygen gas may be used in combination.

A power source used for sputtering may be, for example, any one of a DC power source, an AC power source, an MF power source, or an RF power source, or may be a combination thereof.

The indium oxide-containing layer formed as described above preferably contains an oxide of indium such as indium oxide (In₂O3), indium tin oxide (ITO), and indium zinc oxide (IZO).

Next, the metal layer 12 is laminated on the indium oxide-containing layer 11. Also in this case, for example, a method such as vacuum vapor deposition or sputtering can be used. The indium oxide-containing layer 11 and the metal layer 12 are preferably brought into direct contact with each other without any other layers interposed therebetween.

### Application of Electromagnetic Wave Transmissive Metallic Luster Member

The electromagnetic wave transmissive metallic luster member of the present embodiment has electromagnetic wave transmitting property, and thus is preferably used in an apparatus or an article that transmits and receives electromagnetic waves, a part thereof, and the like. Examples thereof include a structural part for a vehicle, a vehicle-mounted article, a housing of an electronic device, a housing of a home appliance, a structural part, a machine part, various automobile parts, a part for an electronic device, furniture, a household goods application such as kitchen goods, a medical device, a part of a building member, and other structural parts and exterior parts.

More specifically, in a vehicle field, examples thereof include an instrument panel, a console box, a door knob, a door trim, a shift lever, pedals, a glove box, a bumper, a hood, a fender, a trunk, a door, a roof, a pillar, a seat, a steering wheel, an ECU box, an electrical part, an engine peripheral part, a drive system/gear peripheral part, an intake/exhaust system part, and a cooling system part.

More specifically, examples of the electronic device and the home appliance include household electric appliances such as a refrigerator, a washing machine, a vacuum cleaner, a microwave oven, an air conditioner, a lighting device, an electric water heater, a television, a timepiece, a ventilation fan, a projector, and a speaker; and electronic information devices such as a personal computer, a mobile phone, a smartphone, a digital camera, a tablet PC, a portable music player, a portable game machine, a charger, and a battery.

### EXAMPLES

Hereinafter, the present invention will be described in more detail with reference to Examples and Comparative Examples. Various samples were prepared for the electromagnetic wave transmissive metallic luster member 1, and electromagnetic wave transmitting property was evaluated.

As the substrate 10, a substrate film was used.

### Electromagnetic Wave Transmitting Property

### Sheet Resistance

Using Hiresta (Hiresta-UP MCP-HT450 device manufactured by Mitsubishi Chemical Analytech Co., Ltd.), a sheet resistance (Ω/□) of a laminate of a metal layer and an indium oxide-containing layer was measured by an eddy current measurement method in accordance with JIS-Z2316.

A measurement terminal was pressed from a metal layer side of a substrate, and a sheet resistance (a resistance value) was measured when the measurement was performed for 30 seconds using an applied voltage of 1000 V. When a value cannot be measured at 1000 V (1.00 × 10⁸ Ω/□ or less), the applied voltage was changed to 100 V, and a sheet resistance (a resistance value) was measured.

### Evaluation of Sheet Resistance

2.50 E + 8 (Ω/□) or more: o
Less than 2.50 E + 8 (Ω/□): ×

### Reflectance

Using a spectrophotometer (U-4100 device manufactured by Hitachi High-Technologies Corporation), a light-shielding black acrylic plate was attached to a transparent substrate side of a film via an adhesive to prepare an evaluation sample.

Next, a value of a luminous reflectance Y of a metal layer surface was measured under a condition of 5° regular reflection (wavelength: 380 nm to 780 nm).

### State of Metal Layer

When the measurement cannot be performed with the above Hiresta due to a lower limit of measurement, a sheet resistance was measured with a non-contact resistance meter (Hiresta UP MCP-HT450 manufactured by Mitsubishi Chemical Analytech Co., Ltd.).

### Evaluation of Metal Layer

1.00 E + 3 (Ω/□) or more: o
Less than 1.00 E + 3 (Ω/□): ×

### Thickness of Metal Layer

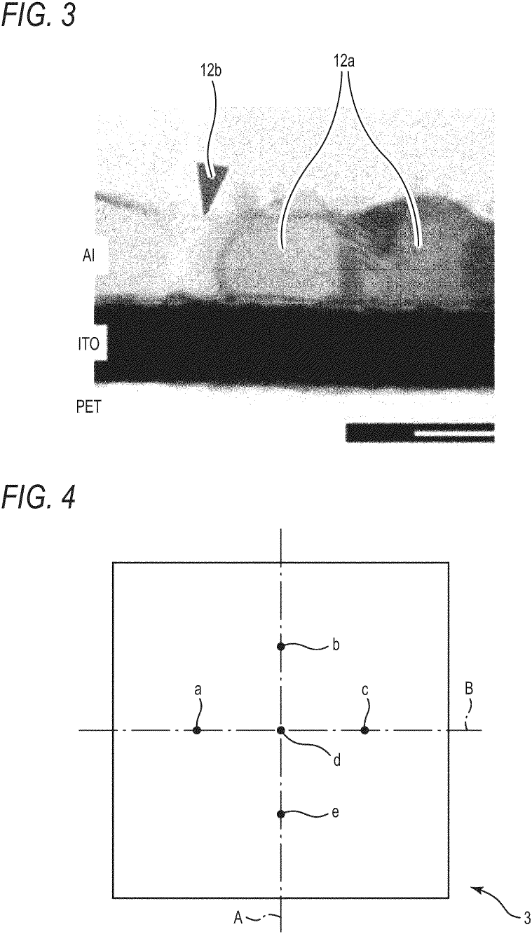

In consideration of a variation in the metal layer, more specifically, a variation in thicknesses of the portions 12a shown in FIG. 1, an average value of the thicknesses of the portions 12a was determined as a thickness of the metal layer (an Al film thickness (nm)). The thickness of each of the portions 12a was a thickness of a thickest portion in a vertical direction from the substrate 10. Hereinafter, this average value is referred to as a “maximum thickness” for convenience. FIG. 3 shows an example of an electron micrograph (a TEM image) of a cross section of the electromagnetic wave transmissive metallic luster member.

When the maximum thickness is to be obtained, first, a square region 3 having one side of 5 cm as shown in FIG. 4 was appropriately extracted from the metal layer appearing on the surface of the electromagnetic wave transmissive metallic luster member as shown in FIG. 3, and a total of five points “a” to “e” obtained by dividing a center line A of vertical sides and a center line B of horizontal sides of the square region 3 into four equal parts were selected as measurement points.

Next, a viewing angle region including approximately five portions 12a at each of the selected measurement points was extracted from the cross-sectional image as shown in FIG. 3. The individual thicknesses (nm) of the approximately five portions 12a at each of the five measurement points, that is, 25 (5 × 5) portions 12a were obtained, and an average value thereof was determined as the “maximum thickness”.

### Thickness of Indium Oxide-Containing Layer

Samples in which an indium oxide-containing layer was adjusted for each thickness were prepared, a transmission electron micrograph (a TEM image) was measured with respect to a net peak intensity measured by a scanning fluorescent X-ray analyzer ZSX Primus II, a thickness of each indium oxide-containing layer was calculated, and a calibration curve of the thickness with respect to the net peak intensity was made. The thickness of the indium oxide-containing layer was calculated based on the net peak intensity of fluorescent X-rays using the calibration curve.

An average value thereof was determined as the thickness of the indium oxide-containing layer (an ITO film thickness (nm)).

### Example 1

As a substrate film, a PET film (thickness: 50 µm) on which a hard coat layer containing no particles was formed was used, and an ITO layer having a thickness of 4.4 nm was directly formed thereon along a surface of the substrate film using MF-AC magnetron sputtering. A temperature of the substrate film at the time of forming the ITO layer was set to 90° C. A content ratio (content ratio = (SnO₂/(In₂O₃ + SnO₂)) × 100) of tin oxide (SnO₂) contained in ITO was 10 wt%. Next, an aluminum (Al) layer having a thickness of 34.5 nm was formed on the ITO layer using alternating current sputtering (MF-AC: 40 kHz) to obtain a metallic luster article (a metal thin film). The obtained aluminum layer was a discontinuous layer. A temperature of the substrate film at the time of forming the Al layer was set to 90° C.

### Examples 2 to 4

In Examples 2 to 4, films were formed in the same manner as in Example 1 except that the thicknesses of the ITO layers were changed to 4.1 nm, 3.8 nm, and 3.4 nm, respectively, and the thicknesses of the Al layers were changed to 34.5 nm, 33.1 nm, and 35.1 nm, respectively.

### Comparative Example 1

In Comparative Example 1, a film was formed in the same manner as in Example 1 except that the thickness of the ITO layer was changed to 3.2 nm. The thickness of Al layer was 32.7 nm.

### Comparative Examples 2 to 5

In Comparative Examples 2 to 5, films were formed in the same manner as in Example 1 except that the thicknesses of the ITO layers were changed to 2.5 nm, 5.2 nm, 6.1 nm, and 8.1 nm, respectively, and the thicknesses of the Al layers were changed to 32.5 nm, 36.9 nm, 29.1 nm, and 29.1 nm, respectively.

### Comparative Example 6

As a substrate film, a PET film (thickness: 50 µm) on which a hard coat layer containing no particles was formed was used.

First, an ITO layer having a thickness of 4.8 nm was directly formed along a surface of the substrate film using DC magnetron sputtering. A temperature of the substrate film at the time of forming the ITO layer was set to 130° C. A content ratio (content ratio = (SnO₂/(In₂O₃ + SnO₂)) × 100) of tin oxide (SnO₂) contained in ITO was 10 wt%.

Next, an aluminum (Al) layer having a thickness of 38.0 nm was formed on the ITO layer using alternating current sputtering (AC: 40 kHz) to obtain a metallic luster article (a metal thin film). The obtained aluminum layer was a discontinuous layer. A temperature of the substrate film at the time of forming the Al layer was set to 130° C.

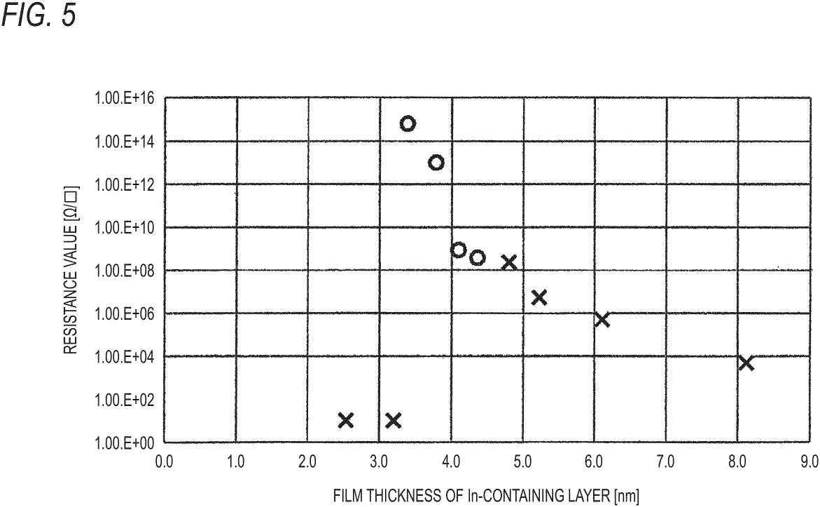

Evaluation results of Examples and Comparative Examples are shown in Table 1 below. FIG. 5 is a diagram showing a relationship between a film thickness (nm) of an indium oxide-containing layer and a sheet resistance (a resistance value Ω/□).

TABLE 1

| | Configuration | Film formation power source of ITO layer | Film formation power source of Al layer | ITO film thickness | Al film thickness | Resistance value | Evaluation of metal layer | Evaluation of sheet resistance | Al surface reflectance |
|---|---|---|---|---|---|---|---|---|---|
| Example 1 | PET#50/HC/ITO/Al/AlOₓ | MF-AC | MF-AC | 4.4 | 34.5 | 3.69.E+08 | ○ | ○ | 71.3 |
| Example 2 | PET#50/HC/ITO/Al/AlOₓ | MF-AC | MF-AC | 4.1 | 34.5 | 8.44.E+08 | ○ | ○ | 70.9 |
| Example 3 | PET#50/HC/ITO/Al/AlOₓ | MF-AC | MF-AC | 3.8 | 33.1 | 1.00.E+13 | ○ | ○ | 70.1 |
| Example 4 | PET#50/HC/ITO/Al/AlOₓ | MF-AC | MF-AC | 3.4 | 35.1 | 6.29.E+14 | ○ | ○ | 70.7 |
| Comparative Example 1 | PET#50/HC/ITO/Al/AlOₓ | MF-AC | MF-AC | 3.2 | 32.7 | 1.00.E+01 | × | × | 68.3 |
| Comparative Example 2 | PET#50/HC/ITO/Al/AlOₓ | MF-AC | MF-AC | 2.5 | 32.5 | 1.02.E+01 | × | × | 68.1 |
| Comparative Example 3 | PET#50/HC/ITO/Al/AlOₓ | MF-AC | MF-AC | 5.2 | 36.9 | 5.36.E+06 | ○ | × | 72.1 |
| Comparative Example 4 | PET#50/HC/ITO/Al/AlOₓ | MF-AC | MF-AC | 6.1 | 29.1 | 5.00.E+05 | ○ | × | 70.3 |
| Comparative Example 5 | PET#50/HC/ITO/Al/AlOₓ | MF-AC | MF-AC | 8.1 | 29.1 | 4.73.E+03 | ○ | × | 70.2 |
| Comparative Example 6 | PET#50/HC/ITO/Al | DC | AC | 4.8 | 38.0 | 2.30.E+08 | ○ | × | 73.1 |

As is clear from Table 1, in metallic luster members of Examples 1 to 4, sheet resistances were 2.50 E + 8 Ω/□or more, and excellent electromagnetic wave transmitting property was exhibited. In addition, reflectance was also sufficient. This is considered to be because formation of a metal layer having an island-shaped discontinuous structure was promoted.

On the other hand, laminated members of Comparative Examples 1 to 6 had a low sheet resistance and inferior electromagnetic wave transmitting property as compared with Examples. This is considered to be because, in Comparative Examples 1 and 2, a resistance value is very small, a thickness of an ITO layer is thin, and an island shape cannot be sufficiently formed, so that a low resistance originated from a metal layer appears. In Comparative Examples 3 to 6, a resistance is not as low as that in Comparative Examples 1 and 2, but is smaller than 2.50 E + 8 Ω/□ This is considered to be because an ITO layer is thick, and thus an island shape is sufficiently formed, but a resistance value originated from the ITO layer appears.

As for metals other than aluminum (Al) particularly used in the above Examples, metals having a relatively low melting point such as zinc (Zn), lead (Pb), copper (Cu), and silver (Ag) can be considered to form a discontinuous structure by the same method.

The present invention is not limited to the above Examples, and can be appropriately modified and embodied without departing from the gist of the invention.

### INDUSTRIAL APPLICABILITY

The electromagnetic wave transmissive metallic luster member according to the present invention can be used in an apparatus or an article that transmits and receives electromagnetic waves, a part thereof, and the like. For example, the present invention can also be applied to various applications requiring both a design and electromagnetic wave transmitting property, such as a structural part for a vehicle, a vehicle-mounted article, a housing of an electronic device, a housing of a home appliance, a structural part, a machine part, various automobile parts, a part for an electronic device, furniture, a household goods application such as kitchen goods, a medical device, a part of a building member, and other structural parts and exterior parts.

Although the present invention has been described in detail with reference to a specific embodiment, it will be apparent to those skilled in the art that various changes and modifications can be made without departing from the spirit and the scope of the present invention.

The present application is based on Japanese Patent Application No. 2020-046758 filed on Mar. 17, 2020, the contents of which are incorporated herein as reference.

### REFERENCE SIGNS LIST

1: electromagnetic wave transmissive metallic luster member
10: substrate
11: indium oxide-containing layer
12: metal layer
12a: portion
12b: gap

1. An electromagnetic wave transmissive metallic luster member comprising: a substrate;
an indium oxide-containing layer provided on the substrate in a continuous state; and
a metal layer formed on the indium oxide-containing layer, wherein
the metal layer includes, in at least a part thereof, a plurality of portions which are in a discontinuous state each other, and
a sheet resistance of a laminate of the metal layer and the indium oxide-containing layer is 2.50 E + 8 Ω/_{□} or more.

2. The electromagnetic wave transmissive metallic luster member according to claim 1, wherein
the indium oxide-containing layer has a thickness of 3.3 nm to 4.6 nm.

3. The electromagnetic wave transmissive metallic luster member according to claim 1, wherein
the indium oxide-containing layer contains any one of indium oxide (In₂O₃), indium tin oxide (ITO), or indium zinc oxide (IZO).

4. The electromagnetic wave transmissive metallic luster member according to claim 1, wherein
the metal layer is a layer containing aluminum or an aluminum alloy.

5. The electromagnetic wave transmissive metallic luster member according to claim 1, wherein
the metal layer has a thickness of 10 nm to 200 nm.

6. The electromagnetic wave transmissive metallic luster member according to claim 1, wherein
the plurality of portions is formed in an island shape.

7. The electromagnetic wave transmissive metallic luster member according to claim 1, wherein
the substrate is any one of a substrate film, a resin molded product substrate, a glass substrate, or an article to which metallic luster is to be imparted.
